(19) United States
(12) Patent Application Publication
(10) Pub. No.: US 2012/0212913 A1
(43) Pub. Date: Aug. 23, 2012

(54) DISPLAY DEVICE HAVING SPEAKER MAGNET FOR CONTROLLING OPERATION STATUS OF DISPLAY THEREOF

(75) Inventors: JI-FENG QIU, Shenzhen City (CN); HONG LI, Shenzhen City (CN); XIAO-HUI ZHOU, Shenzhen City (CN); HAI-TAO WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/080,614

(22) Filed: Apr. 5, 2011

(30) Foreign Application Priority Data
Feb. 17, 2011 (CN) 201110039678.7

(51) Int. Cl. H05K 5/03; H05K 7/00

(52) U.S. Cl. 361/752; 361/679.01

(57) ABSTRACT

An exemplary electronic device includes a main housing and a cover pivotably attached to the main housing. The main housing has a printed circuit board received therein. A Hall sensor is fixed and electrically connected to the printed circuit board. The cover has a display and a speaker located adjacent to the display. The speaker includes a magnet. The Hall sensor can detect variation of a magnetic field of the magnet to output different voltages, thereby actuating the display to turn on or turn off.

### BACKGROUND

1. Technical Field

The present disclosure relates to a display device having a cover, a display provided in the cover, and means for automatically controlling an operating status of the display.

2. Description of Related Art

Display devices play an important role in people's daily lives, showing images and text for all kinds of purposes. For some types of display devices, such as notebooks, digital video players or other portable devices, power consumption is always a concern, particularly when the space available for batteries is limited. Thus, the display of the display device is required to be turned off to save power when the display device is not in use. Notebooks, digital video players, and other portable devices typically comprise a main housing and a display rotatable up from the housing. For such display devices, one way in which turning off of the display may be implemented is by rotating the display down to a closed position engaged with the housing. In order to realize such automatic turnoff of the display, the display and the housing generally have a magnet and a Hall sensor mounted therein, respectively. The Hall sensor detects variation of the magnetic field associated with the magnet when the display is rotated towards the housing, and thereupon produces a signal that is sent to a controlling element to turn the display off.

However, the magnet mounted in the display occupies a certain space, and various electronic elements within the display need to be specially designed and configured to avoid the magnetic field of the magnet. Thus the interior structure of the display is complicated, and this increases the manufacturing cost of the display device.

What is needed, therefore, is a display device which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an isometric, assembled view of a display device in accordance with an embodiment of the present disclosure, wherein a part of the display device is cut away to show an interior of the display device.

FIG. 2 is an enlarged view of a circled part II of FIG. 1.

FIG. 3 is essentially an enlarged view of the part of the display device of FIG. 1 which is cut away, showing a Hall sensor and a tab exploded from the interior of the display device for clarity.

### DETAILED DESCRIPTION

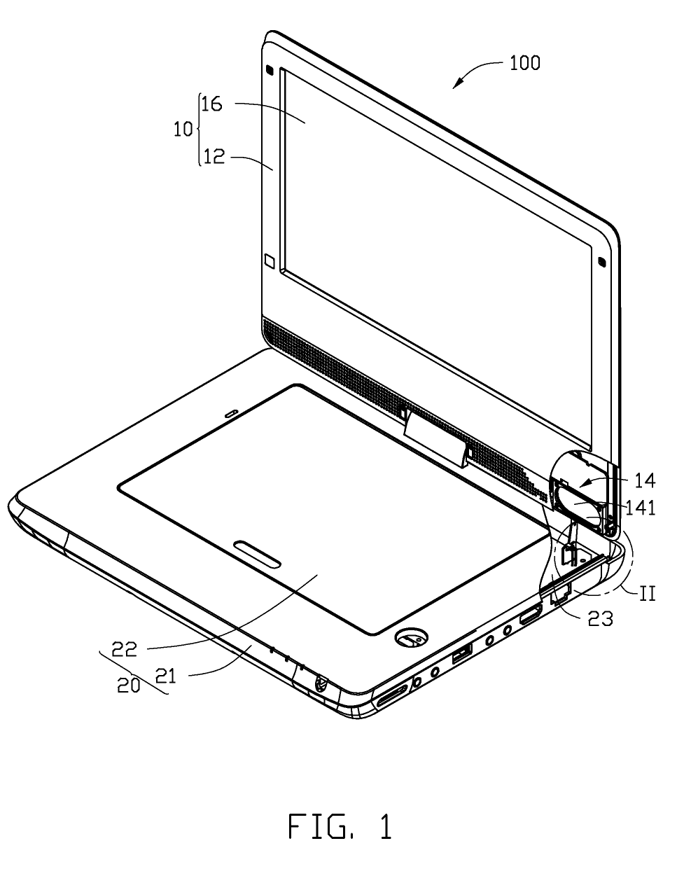

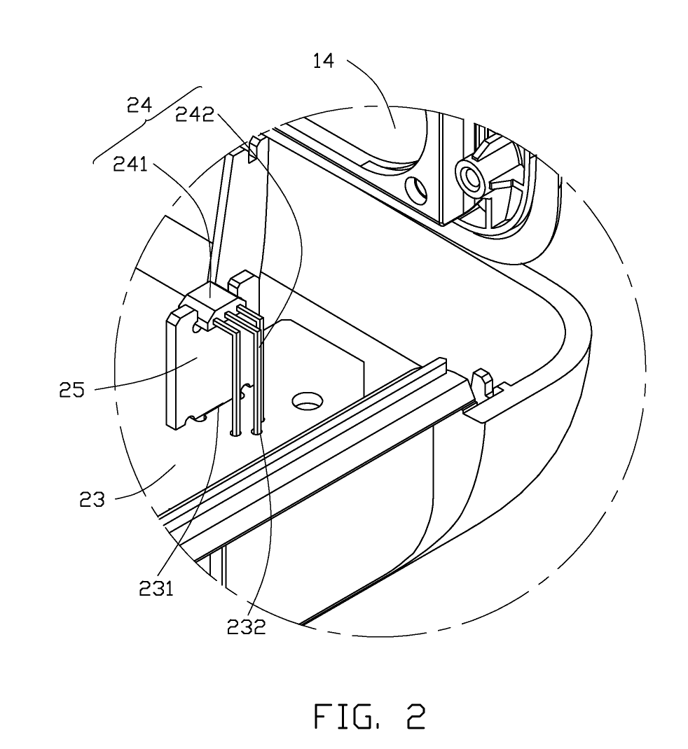

Referring to FIGS. 1-2, a display device 100 in accordance with an embodiment of the present disclosure is shown. The display device 100 includes a main housing 20, and a cover 10 pivotably attached to the main housing 20.

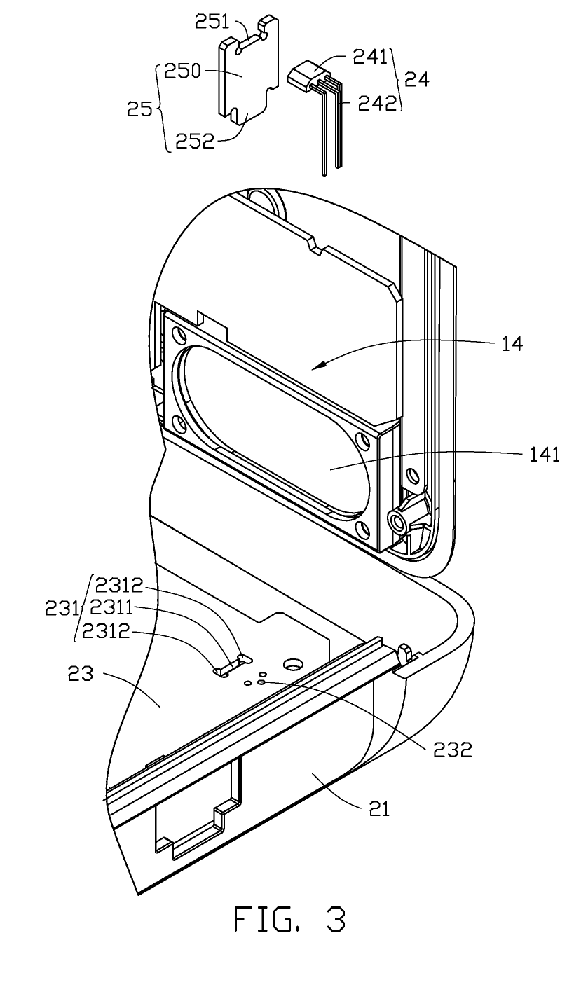

Also referring to FIG. 3, the main housing 20 includes an enclosure 21 and a door 22 rotatably fixed to the enclosure 21. The door 22 can be opened to expose a disk compartment (not shown) of the main housing 20. A disk (not shown) can be put into the disk compartment to provide video (and audio) data. The enclosure 21 has a printed circuit board 23 and a plurality of electronic components (not shown) received therein. The printed circuit board 23 defines a slot 231 and three through holes 232 adjacent to a corner thereof. The slot 231 includes a first portion 2311, and a pair of second portions 2312 located at two opposite ends of the first portion 2311. The first portion 2311 is perpendicular to the second portions 2312 and communicates with the second portions 2312. The first portion 2311 has a length larger that that of each second portion 2312. The three holes 232 are located neighboring the slot 231, and are arranged in a triangle.

A Hall sensor 24 includes a package 241, and three pins 242 extending downwardly from a lateral side of the package 241. The package 241 has electronic elements (not shown) packaged therein to detect variations of any magnetic field around the Hall sensor 24. When a variation of a magnetic field is detected, the package 241 generates a corresponding voltage. The three pins 242 are inserted into the three holes 232 of the printed circuit board 23 to electrically connect with the printed circuit board 23. The three pins 242 include a grounded pin 242, a voltage-output pin 242, and a power-input pin 242. The grounded pin 242 is used for preventing static electricity or leaked electricity from damaging the Hall sensor 24. The power-input pin 242 is used for providing power from the printed circuit board 23 to the Hall sensor 24. The voltage-output pin 242 is used for outputting the voltage of the Hall sensor 24 to the printed circuit board 23.

A tab 25 is inserted into the slot 231 to support the Hall sensor 24 on the printed circuit board 23. The tab 25 includes a body 250, and a protrusion 252 protruding downwardly from a bottom face of the body 250. The body 250 defines a recess 251 in a top edge thereof. The recess 251 has a width larger than that of the package 241 of the Hall sensor 24 so that the package 241 can be received in the recess 251. The body 250 has a width larger than that of the slot 231, and the protrusion 252 has a width smaller than that of the slot 231. The protrusion 252 extends through the slot 231 to protrude downwardly beyond a bottom face of the printed circuit board 23. The protrusion 252 can be soldered to the printed circuit board 23 to be fixed with the printed circuit board 23. The body 250 is held in position by the protrusion 252, such that the body 250 presses against a top face of the printed circuit board 23 and the tab 25 is erect on the printed circuit board 23. The protrusion 252 fully fills the first portion 2311 of the slot 231 and partially fills each second portion 2312. That is, opposite distalmost ends of each of the second portions 2312 remain empty. The empty ends of the second portions 2312 can receive excess solder during soldering of the protrusion 252 to the printed circuit board 23.

The cover 10 is pivotably attached to a side of the enclosure 21 via a shaft (not labeled). The cover 10 includes a frame 12, and a display 16 mounted in the frame 12. The display 16 has a large area exposed to the outside for showing images and text. The frame 12 has a speaker 14 received therein. The speaker 14 is located adjacent to the display 16. The speaker 14 can be driven to produce sound. The speaker 14 includes a magnet 141 located at a corner of the frame 12, corresponding to the Hall sensor 24 in the main housing 20. The magnet 141 is used for interacting with wires (not shown) of the speaker 14. The wires are electrified according to, e.g., a sound track of the disk (not shown), thereby producing desired sound.

When the cover 10 is rotated down to a location close to the main housing 20, the magnetic field of the magnet 141 of the speaker 14 in the vicinity of the Hall sensor 24 becomes strong. The Hall sensor 24 detects the increase in the strength of the magnetic field, and correspondingly outputs a large voltage to a controlling element (not shown) inside the display device 100. The controlling element generates and sends a signal to turn off the display 16 in response to the large voltage of the Hall sensor 24. When the cover 10 is pivoted up away from the main housing 20 to an opened position, the Hall sensor 24 detects a decrease in the strength of the magnetic field of the magnet 141, and correspondingly outputs a small voltage to the controlling element. The controlling element then controls the display 16 to be energized. Thus, the display 16 can be automatically switched off and switched on by the Hall sensor 24. Furthermore, the magnet 141 is incorporated within the speaker 14. Thus, unlike with conventional display devices, the frame 12 does not need another magnet, and does not need a dedicated space for mounting of such magnet therein.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. An electronic device comprising:
a cover comprising a display;
a main housing, the cover movably attached to the main housing;
a speaker mounted to one of the cover and the main housing, the speaker comprising a magnet; and
a Hall sensor mounted to the other of the cover and the main housing;
wherein the Hall sensor is located corresponding to the magnet and electrically connected to the display, and the Hall sensor is operable to detect variation of a magnetic field of the magnet and to correspondingly actuate switching of the display between an on status and an off status.

2. The electronic device of claim 1, wherein the main housing comprises a printed circuit board, the Hall sensor being fixed to the printed circuit board.

3. The electronic device of claim 2, wherein the Hall sensor comprises a package and a plurality of pins inserted into the printed circuit board.

4. The electronic device of claim 3, wherein the plurality of pins comprises a grounded pin, a voltage-output pin and a power-input pin.

5. The electronic device of claim 3, wherein the main housing comprises a tab fixed to the printed circuit board, the package of the Hall sensor being supported by the tab.

6. The electronic device of claim 5, wherein the tab comprises a body defining a recess in a top edge thereof, the package of the Hall sensor being received in the recess.

7. The electronic device of claim 6, wherein the tab has a protrusion extending downwardly from a bottom of the body, the printed circuit board defining a slot receiving the protrusion.

8. The electronic device of claim 7, wherein the slot comprises a first portion and a pair of second portions located at two opposite ends of the first portion, each of the second portions being perpendicular to the first portion.

9. The electronic device of claim 8, wherein the protrusion partially fills each of the second portions of the slot, with opposite distalmost ends of each of the second portions not being filled by the protrusion.

10. The electronic device of claim 1, wherein the cover is pivotable relative to the main housing.

11. The electronic device of claim 1, wherein the Hall sensor is located at a corner of the main housing, and the magnet is located at a corner of the cover adjacent to the corner of the main housing.

12. The electronic device of claim 1, wherein Hall sensor is located lower than the magnet.

13. An electronic device comprising:
a display;
a printed circuit board electrically connected to the display, the display being movable relative to the printed circuit board;
a Hall sensor electrically connected to the printed circuit board; and
a speaker having a magnet incorporated therein;
wherein the magnet is movable relative to the Hall sensor in unison with movement of the display relative to the printed circuit board, and the Hall sensor is configured to detect variation of a magnetic field associated with the moving magnet and thereby effectuate switching of the display between an operation status and a shutdown status.

14. The electronic device of claim 13, wherein the printed circuit board has a tab mounted thereon, the Hall sensor being supported by the tab.

15. The electronic device of claim 14, wherein the tab has a body defining a recess and a protrusion inserted into the printed circuit board, the Hall sensor being received in the recess.

16. The electronic device of claim 13, wherein the speaker is located adjacent to the display and the Hall sensor is located on the printed circuit board.

17. The electronic device of claim 13, wherein the display is received in a cover, and the printed circuit board is received in a main housing, the cover being pivotable with respect to the main housing.

18. An electronic device comprising:
a main housing comprising a printed circuit board and a Hall sensor mounted on the printed circuit board; and
a cover pivotably attached to the main housing, the cover comprising a display and a speaker mounted in the vicinity of the display;
wherein the speaker comprises a magnet incorporated therein, the magnet being movable relative to the Hall sensor, and the Hall sensor being operable to detect variation of a magnetic field associated with the magnet and thereby actuate switching of the display between an off status and an on status.

19. The electronic device of claim 18, wherein the main housing comprises a tab supporting the Hall sensor on the printed circuit board.

20. The electronic device of claim 18, wherein the magnet is located at a corner of the cover, and the Hall sensor is located at a corner of the main housing corresponding to the magnet.
